(19) United States
(12) Patent Application Publication
(10) Pub. No.: US 2020/0252068 A1
(43) Pub. Date: Aug. 6, 2020

(54) SINGLE SUPPLY CLOCKED VOLTAGE LEVEL TRANSLATOR WITH LATCH FUNCTIONALITY

(71) Applicant: International Business Machines Corporation, Armonk, NY (US)

(72) Inventors: Arindam RAYCHAUDHURI, Bangalore (IN); Dharshak Balappa SOMASHEKAR, Bangalore (IN); Sumantra SARKAR, Bangalore (IN)

(21) Appl. No.: 16/266,861

(22) Filed: Feb. 4, 2019

(51) Int. Cl. H03K 19/0185; H03K 3/356

(52) U.S. Cl. CPC H03K 19/018521; H03K 3/356165; H03K 3/356113

(57) ABSTRACT

Techniques for a combined voltage translator and latch circuit. The circuit translates a signal from a first voltage domain in an integrated circuit to a second voltage domain in the integrated circuit and acts as a latch for the signal. The circuit includes a regenerative feedback loop, including an input node an output node, a first inverter, and a first transistor. The input node is coupled to the first transistor and an input of the first inverter. The output node is coupled to an output of the first inverter and a gate of the first transistor.

### BACKGROUND

The present disclosure relates to microprocessor technology, and more specifically, though not exclusively, to voltage level translation with latch functionality.

In electronic microprocessors and other integrated circuits, multiple supply voltage domain (MSVD) techniques can be used to partition the microprocessor into different voltage domains or islands, enabling each island to operate at a different rail voltage to meet its timing demands. These configurations can use voltage level translators to transfer signals from lower to higher voltage islands, and vice versa. For example, voltage level translators can be used to translate between voltage domains when exchanging handshake signals between two logic units of a microprocessor operating at different voltages. MSVD techniques are becoming more and more common in modern microprocessor systems, which can include many different processor cores operating at different voltage levels. These techniques are also becoming more common in modern system on chip (SoC) systems, in which multiple processors and other components can be linked on a single chip.

### SUMMARY

Embodiments described herein include a microprocessor. The microprocessor includes a first portion operating in a first voltage domain, a second portion operating in a second voltage domain, and a circuit configured to translate a signal from the first voltage domain to the second voltage domain and to act as a latch for the signal. The circuit includes a regenerative feedback loop, including an input node, an output node, a first inverter, and a first transistor. The input node is coupled to the first transistor and an input of the first inverter, and the output node is coupled to an output of the first inverter and a gate of the first transistor.

Embodiments described herein further include a combined voltage translator and latch circuit configured to translate a signal from a first voltage domain in an integrated circuit to a second voltage domain in the integrated circuit and to act as a latch for the signal. The circuit includes a regenerative feedback loop, including an input node an output node, a first inverter, and a first transistor. The input node is coupled to the first transistor and an input of the first inverter. The output node is coupled to an output of the first inverter and a gate of the first transistor.

Embodiments described herein further include a method for translating between voltage domains in a microprocessor. The method includes translating a signal from a first voltage domain in a first portion of the microprocessor to a second voltage domain in a second portion of the microprocessor, using a circuit. The method further includes latching the signal at the second voltage domain, using the circuit. The circuit includes a regenerative feedback loop, including an input node, an output node, a first inverter, and a first transistor. The input node is coupled to the first transistor and an input of the first inverter. The output node is coupled to an output of the first inverter and a gate of the first transistor.

### BRIEF DESCRIPTION OF THE SEVERAL VIEWS OF THE DRAWINGS

FIG. 1 illustrates a microprocessor including multiple voltage domains and a voltage level translator, according to one embodiment described herein.

FIGS. 2A-B illustrate a microprocessor including multiple voltage domains, a voltage level translator, and a latch, according to one embodiment described herein.

FIG. 3 illustrates a microprocessor including multiple voltage domains and a combined voltage level translator and latch, according to one embodiment described herein.

FIG. 4 further illustrates a microprocessor including multiple voltage domains and a combined voltage level translator and latch, according to one embodiment described herein.

FIG. 5 illustrates a simulation of operation of a combined voltage level translator and latch, according to one embodiment described herein.

FIG. 6 illustrates a simulation of operation of an improved latch, according to one embodiment described herein.

FIG. 7 illustrates an example computer, according to one embodiment described herein.

### DETAILED DESCRIPTION

As noted above, multiple supply voltage domain (MSVD) techniques can be used to partition the microprocessor into different voltage domains or islands. This can be done for single core systems, multiple core systems, system on chip (SoC) systems, and other integrated circuits. These configurations can use voltage level translators to transfer signals from lower to higher voltage islands, and vice versa. For example, a voltage level translator can be used to translate a handshake signal transmitted between voltage domains operating at different rail voltages. Further, such systems can use a latch to prevent unwanted data or signal intrusion, due to noise, after the relevant communication between voltage domains has ended. The latch can help avoid reception of erroneous signals and thereby prevent the receiver from malfunctioning.

In some systems, translation between voltage domains is done using a system including 1) a driver within the transmitter unit, 2) a voltage level translator on the channel and 3) a latch inside the receiver unit. The voltage level translator translates between voltage domains, while a separate latch helps avoid reception of erroneous signals by the receiver. But there can be significant drawbacks to this approach. For example, this can result in a large delay in transferring the signal from the transmitter logic unit to the receiver unit. Further, this can result in a larger circuit area and higher power consumption, stemming from a separate voltage level translator and latch. As a further example, this technique can result in meta-stability (e.g., a voltage level between logical “0” and “1”) in the receiver latch.

Some, or all, of these drawbacks can be avoided through an improved solution, according to one or more embodiments herein. In particular, according to some embodiments, the functionalities of a voltage level translator and latch can be combined into a single innovative circuit, rather than having separate voltage level and latch circuits. Among other potential advantages, this can reduce the signal transfer delay from a transmitter logic unit to the receiver logic unit, decrease the circuit area used by blending a voltage level translator and latch into one single circuit, reduce power consumption, and reduce meta-stability problems.

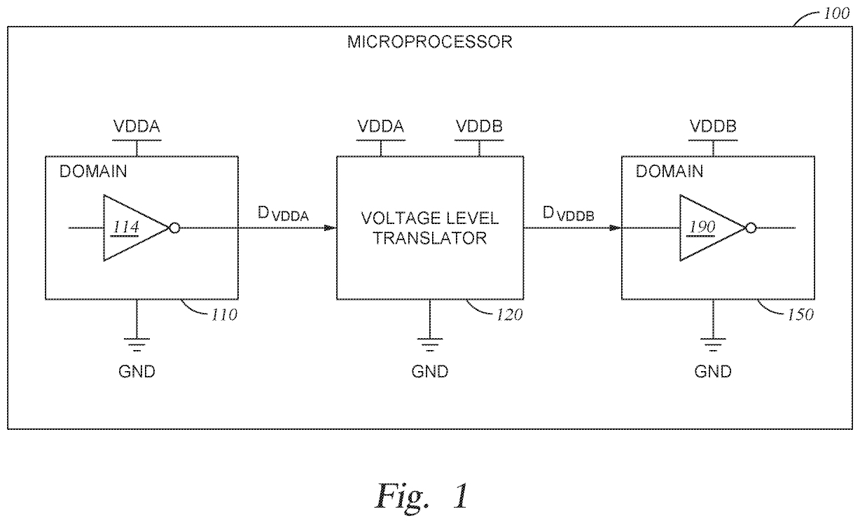

FIG. 1 illustrates a microprocessor 100 including multiple voltage domains and a voltage level translator, according to one embodiment described herein. The microprocessor 100 includes a first voltage domain 110 operating at rail voltage VDDA and a second voltage domain 150 operating at rail voltage VDDB. In an embodiment, VDDA is different from VDDB. In an embodiment, a voltage level translator 120 translates between the voltage domain 110 and the voltage domain 150. For example, the voltage domain 110 includes a driver 114. The driver 114 drives a data signal D_{VDDA} at rail voltage VDDA. The voltage level translator 120 receives the data signal D_{VDDA} and converts it to a data signal D_{VDDB} representing the same data, but now operating at rail voltage VDDB. The voltage level translator provides the data signal D_{VDDB} to a driver 190 operating in the second voltage domain 150. In an embodiment, the voltage level translator 120 takes both rail voltage levels as input: VDDA and VDDB.

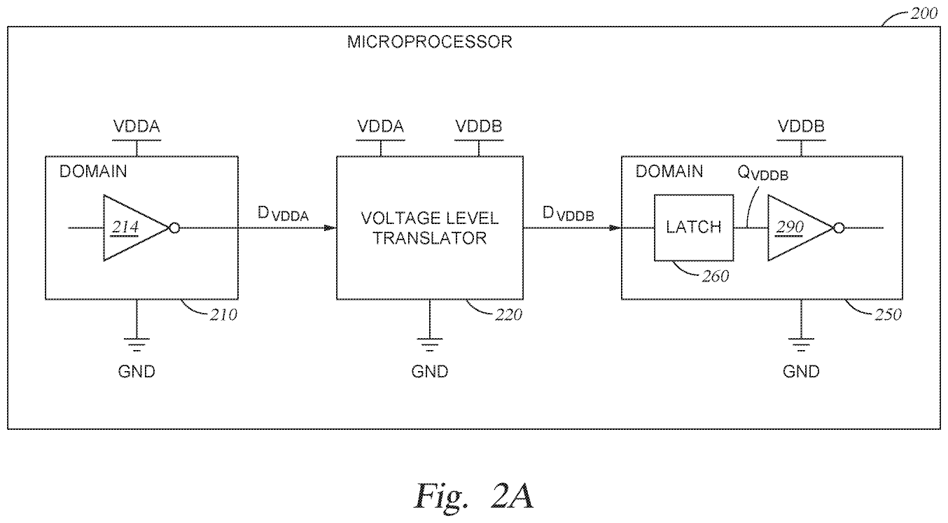

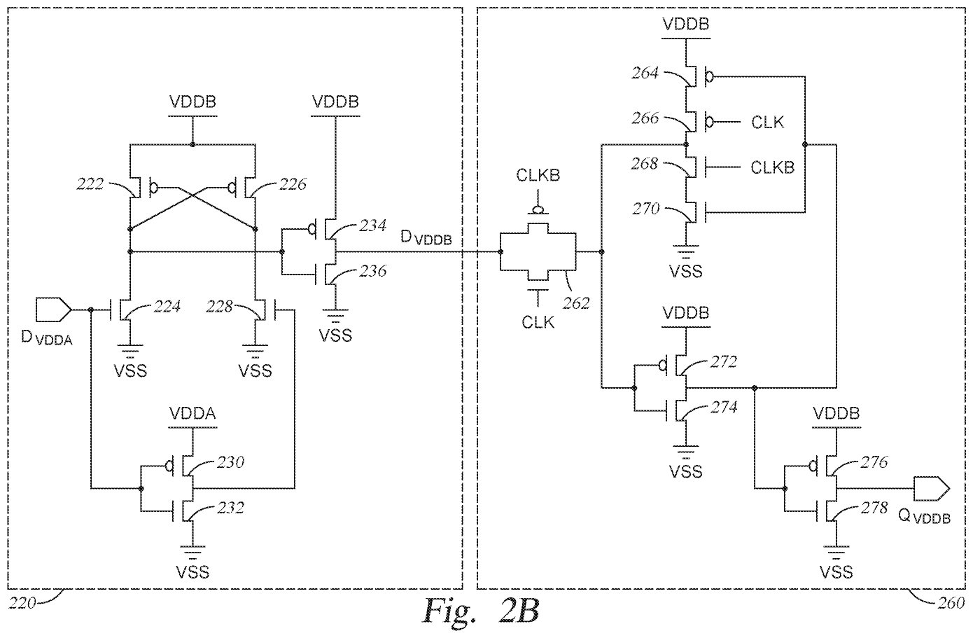

FIGS. 2A-B illustrate a microprocessor 200 including multiple voltage domains, a voltage level translator, and a latch, according to one embodiment described herein. FIG. 2A is a block diagram illustrating the microprocessor 200. As illustrated in FIG. 2A, the microprocessor 200 includes a first voltage domain 210 operating at rail voltage VDDA and a second voltage domain 250 operating at rail voltage VDDB. In an embodiment, VDDA is different from VDDB. In an embodiment, a voltage level translator 220 translates between the voltage domain 210 and the voltage domain 250.

For example, the voltage domain 210 includes a driver 214. The driver 214 drives a data signal D_{VDDA} at rail voltage VDDA. The voltage level translator 220 receives the data signal D_{YDDA} and converts it to a data signal D_{VDDB} representing the same data, but now operating at rail voltage VDDB. In an embodiment, the voltage level translator 220 takes both rail voltage levels as input: VDDA and VDDB. The voltage domain 250 includes a latch 260 and a driver 290. In an embodiment, the voltage level translator 220 provides the data signal D_{VDDB} to the latch 260, which latches the data value Q_{VDDB} and provides it to the driver 290.

FIG. 2B is a circuit diagram illustrating a voltage level translator 220 and a latch 260 (e.g., the voltage level translator 220 and the latch 260 illustrated in FIG. 2A). The voltage level translator 220 includes two source voltage levels: VDDA and VDDB. In an embodiment, as discussed above with regard to FIG. 2A, VDDA is the rail voltage of a first voltage domain (e.g., the voltage domain 210 illustrated in FIG. 2A) and VDDB is the rail voltage of a second voltage domain (e.g., the voltage domain 250 illustrated in FIG. 2A). The voltage level translator 220 receives an input data signal D_{VDDA}, operating at the rail voltage level VDDA. D_{VDDA} drives the gate of a transistor 224 (e.g., an n-channel field effect transistor (FET)). VDDB is coupled to two transistors 222 and 226 (e.g., two p-channel FETs). The gate of the transistor 226 is coupled to the transistor 224, while the gate of the transistor 222 is coupled to the transistor 228. The input data signal D_{VDDA} is further coupled to the gates of two transistors: a p-channel transistor 230 and an n-channel transistor 232. The input voltage VDDA is further coupled to the transistor 230, and both the transistors 230 and 232 are coupled to the gate of the n-channel transistor 228.

The transistor 224 is further coupled to the gates of two additional transistors: a p-channel transistor 234 and an n-channel transistor 236. The p-channel transistor 234 is further coupled to VDDB. The output data signal D_{VDDB} is coupled to the transistors 234 and 236. In an embodiment, the voltage level translator 220 serves to convert the input data signal D_{YDDA} from one voltage domain (e.g., operating at rail voltage VDDA) to a second voltage domain (e.g., operating at rail voltage VDDB). The output data signal D_{VDDB} represents the same data value as the input data signal D_{VDDA}, but at a different rail voltage.

In an embodiment, the voltage level translator 220 is coupled to the latch 260 to avoid erroneous data capture when a clock signal is inactive. In an embodiment, the latch 260 captures the data signal D_{VDDB} when a clock signal CLK is high. The output data signal D_{VDDB} from the voltage level translator 220 is coupled to a transmission gate 262 in the latch 260. The transmission gate 262 operates as a switch, with the clock signal CLK and an inverse clock signal CLKB as the control. The source rail voltage VDDB is further coupled to a p-channel transistor 264, while the output of the transmission gate 262 is coupled to a p-channel transistor 272 and an n-channel transistor 274. The gates of p-channel transistor 276 and n-channel transistor 278 are coupled to the transistors 272 and 274. A transistor 270 is coupled to the transistor 268 and a drain VSS. The gates of the transistors 264 and 270 are coupled to two transistors 272 and 274, while the gate of the transistor 266 is coupled to the clock signal CLK and the gate of the transistor 268 is coupled to the inverse clock signal CLKB. In an embodiment, the clock signal CLK and inverse clock signal CLKB can be generated using an inverter, or another suitable circuit.

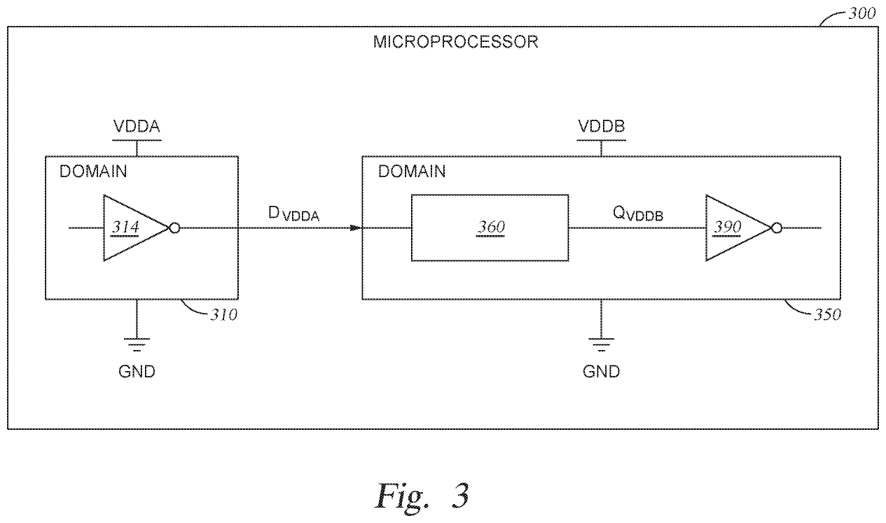

FIG. 3 illustrates a microprocessor including multiple voltage domains 310 and 350 and a combined voltage level translator and latch circuit 360, according to one embodiment described herein. As illustrated in FIG. 3, the microprocessor 300 includes a first voltage domain 310 operating at rail voltage VDDA and a second voltage domain 350 operating at rail voltage VDDB. In an embodiment, VDDA is different from VDDB. In an embodiment, a circuit 360 combining a voltage level translator and latch translates between the voltage domain 310 and the voltage domain 350. As an example, the microprocessor 300 illustrated in FIG. 3 combines the functions of the voltage level translator 220 and the latch 260, illustrated in FIG. 2A, into a single circuit 360.

For example, the voltage domain 310 includes a driver 314. The driver 314 drives a data signal D_{VDDA} at rail voltage VDDA. The circuit 360 receives the data signal D_{VDDA} and converts it to a data signal D_{VDDB} representing the same data, but now operating at rail voltage VDDB. In an embodiment, the circuit 360 further acts as a latch, capturing the value of V_{DDB} when a clock signal is high. In an embodiment, the circuit 360 takes only the rail voltage VDDB as input—in this embodiment, the circuit 360 does not need VDDA as input. In an embodiment, the circuit 360 provides a data signal Q_{VDDB} which is level translated and latched, operating at the rail voltage VDDB, to a driver 390.

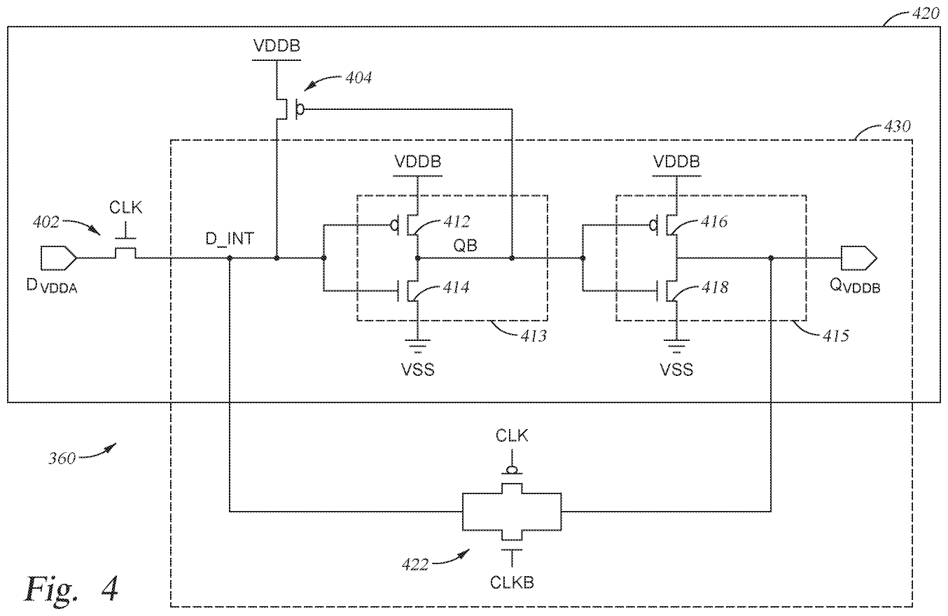

FIG. 4 further illustrates a combined voltage level translator and latch (e.g., the circuit 360 illustrated in FIG. 3) inside the microprocessor 300, according to one embodiment described herein. A transistor 402 (e.g., an n-channel transistor) is coupled to an input data signal D_{VDDA}. In an embodiment, the signal D_{YDDA} operates at the input rail voltage VDDA. The transistor 402 is further coupled to an intermediate data signal node labeled D_INT. The gate of the transistor 402 is coupled to a clock signal CLK. A transistor 404 (e.g., a p-channel transistor) is coupled to a voltage source operating at a voltage VDDB, to the transistor 402 (e.g., the signal D_INT), and to the gates of transistors 412 (e.g., a p-channel transistor) and 414 (e.g., an n-channel transistor). In an embodiment, the transistors 412 and 414 form an inverter 413 for the signal coupled to the gates of the transistors (e.g., D_INT). The signal D_INT is further coupled to a transmission gate 422. The transmission gate 422 operates as a switch, with the clock signal CLK and the inverse clock signal CLKB as controls.

The transistor 412 is further coupled to a voltage source operating at rail voltage VDDB and to the transistor 414. The transistor 414 is further coupled to a drain VSS. The node QB is coupled to both the transistors 412 and 414, and to the gate of the transistor 404. The node QB is further coupled to the gates of transistors 416 (e.g., a p-channel transistor) and 418 (e.g., an n-channel transistor). The transistors 416 and 418 are coupled together, the transistor 416 is coupled to a voltage source operating at VDDB, the transistor 418 is coupled to a drain VSS, and the transistors 416 and 418 are coupled to the transmission gate 422. In an embodiment, the transistors 416 and 418 form an inverter 415 for the signal coupled to the gates of the transistors (e.g., QB).

The signal node QB is further coupled to the gate of the transistor 404. In an embodiment, this forms a regenerative feedback loop between the signals D_INT and QB. The node D_INT acts as an input node while the node QB acts as an output node. In an embodiment, the components within the box labeled 420 form a voltage level translator between VDDA and VDDB, while the components within the box labeled 430 form a latch. This allows the combined circuit, including shared components between the boxes 420 and 430, to act as both a voltage level translator and latch. The regenerative feedback loop between D_INT and QB, discussed above, facilitates voltage translation from a domain operating at rail voltage VDDA to a domain operating at rail voltage VDDB for the input data signal D_{YDDA}. The regenerative feedback loop ensures that the input to the inverters 413 and 415 is pulled to the rail voltage VDBB, instead of VDDA or somewhere between VDDA and VDDB. At the same time, the transmission gate 422 combines with the other components in the box 430 to act as a latch on the data signal, avoiding erroneous data capture when the clock signal CLK is low. The output of the circuit 360 is a data signal Q_{VDDB}, which matches the data value of the input data signal D_{VDDA} but operates at the rail voltage VDDB instead of VDDA. Further, the latch effect limits erroneous data capture for Q_{VDDB} when the clock signal is low.

There are many potential advantages to the embodiment illustrated in FIGS. 3 and 4. For example, the combined voltage translator and latch circuit 360 can provide significantly less delay than a circuit with a separate voltage translator and latch (e.g., circuits 220 and 260 illustrated in FIG. 2). In an embodiment, this is because there is a closer match between the rise delay and the fall delay. For example, in at least one simulation, given a rail voltage of 0.6V for VDDA and 1.1V for VDDB the rise delay in a circuit with a separate latch and voltage translator could be 55.6 psec. With the techniques illustrated in FIGS. 3 and 4, this could be reduced in the simulation by more than 70% to 15.7 psec. Similarly, in a given simulation the fall delay could be reduced from 87.5 psec to 14.1 psec, a reduction of more than 80%. Further, in an embodiment, the combined voltage translator and latch circuit 360 provides less duty cycle distortion for the clock.

Another potential advantage is a reduction in current usage. In an embodiment, in a circuit with a separate voltage translator and latch (e.g., circuits 220 and 260 illustrated in FIG. 2) the voltage translator is always active, regardless of the clock state (e.g., when the clock is low the latch may be inactive but the voltage translator remains active). In the combined voltage translator and latch circuit 360 illustrated in FIGS. 3 and 4, both the voltage translator and latch components are active only when the clock is active (e.g., when the clock is low both the voltage translator and latch components are inactive). This can result in a significant savings in current consumption. Further, as another example, the combined voltage translator and latch circuit 360 illustrated in FIGS. 3 and 4 requires less circuit area and uses fewer transistors than a separate voltage translator and latch (e.g., circuits 220 and 260 illustrated in FIG. 2).

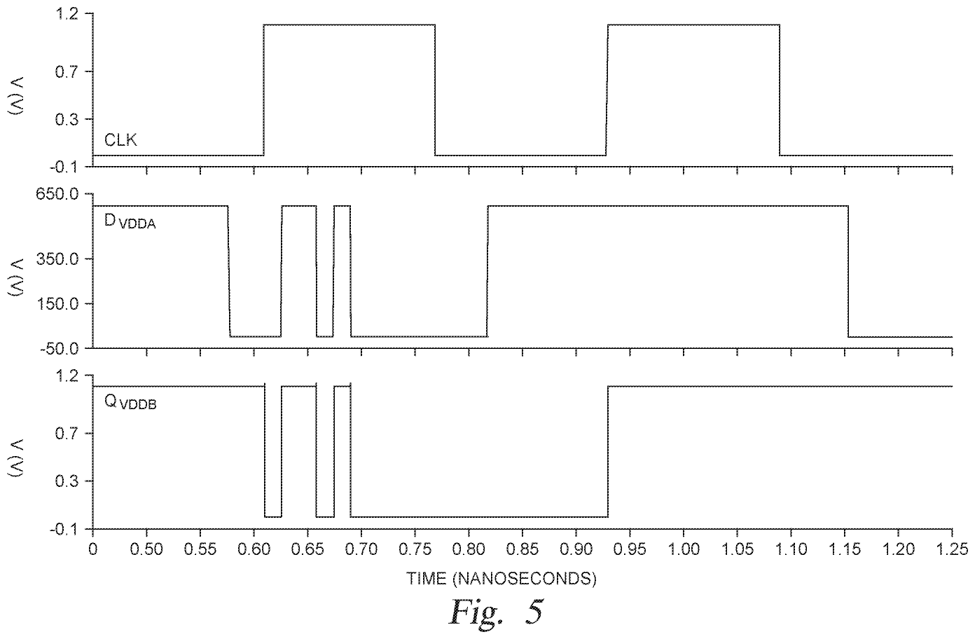

FIG. 5 illustrates a simulation of operation of a combined voltage level translator and latch (e.g., the circuit 360 illustrated in FIGS. 3 and 4), according to one embodiment described herein. The signal CLK represents the clock, the signal D_{VDDA} represents an input data signal, and the signal Q_{VDDB} represents an output data signal. The x-axis represents time in microseconds, while the y-axes of the three graphs each represent a voltage (e.g., in V or mV). As can be seen from FIG. 5, the circuit 360 acts as both a voltage converter and latch. The circuit 360 acts as a voltage converter by converting from a first voltage domain for the input signal D_{VDDA} to a second voltage domain for the output signal Q_{VDDB}. For example, the input signal D_{YDDA} has a high voltage (e.g., representing a data value of “1”) of about 650 mV (i.e., 0.65V). The output signal Q_{VDDB} has been converted to a higher voltage domain VDDB, and has a high voltage (e.g., representing a data value of “1”) of about 1.2V. Thus, the circuit 360 acts as a voltage translator between voltage domains.

The circuit 360 acts as a latch by only changing the value of Q_{VDDB} to match D_{VDDA} when the clock signal CLK is high. For example, at approximately time 0.8 μs the value for D_{VDDA} transitions from high to low (e.g., from approximately 650 mV to approximately 0). But the clock signal CLK is low, so the output signal Q_{VDDB} does not change until the clock signal CLK goes high at time 1.0 μs. At time 1.1 μs, the value of D_{VDDA} transitions from low to high. This time, the output signal Q_{VDDB} follows suit, also transitioning from low to high, because the clock signal CLK is high.

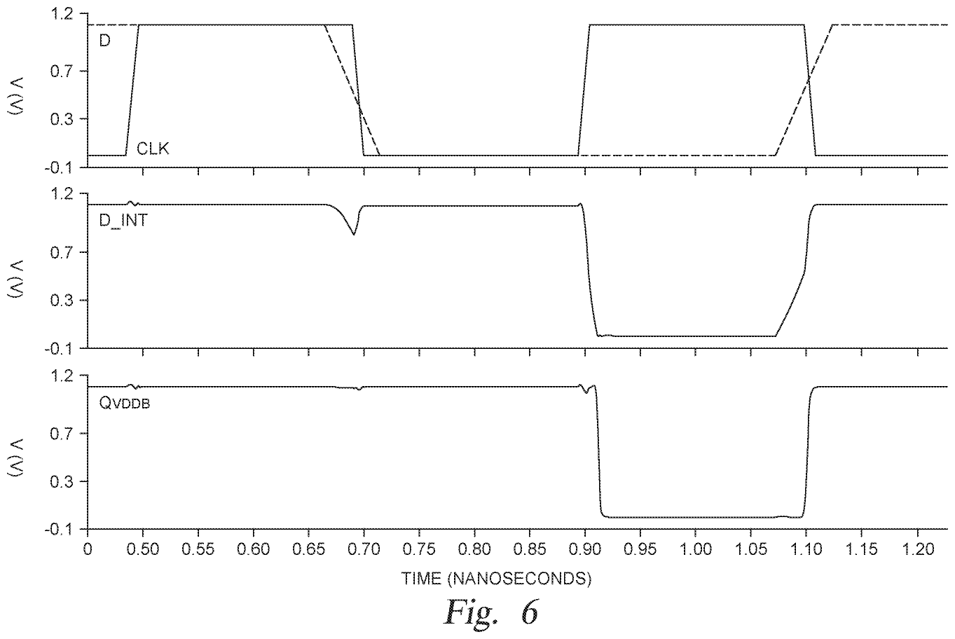

FIG. 6 illustrates a simulation of operation of an improved latch, according to one embodiment described herein. In addition to acting as a combined voltage translator and latch, the circuit 360 illustrated in FIG. 4 can operate as an improved latch, reducing problems with meta-stability. In one example, meta-stability is undesirable because it can result in logical failures, and can result in waste of power and chip failure. In an embodiment, the regenerative feedback loop (e.g., between D_INT and QB in FIG. 4, as discussed above), serves to pull the value of Q_{VDDB} high (or low, as appropriate) and to avoid meta-stability issues that might be present in another latch design (e.g., the latch 260 illustrated in FIG. 2B). In an embodiment, if the value of D_{VDDA} is somewhat above 0 but below VDDA, the generative feedback loop (e.g., between D_INT and QB in FIG. 4, as discussed above) pulls the value of Q_{VDDB} to VDDB to avoid meta-stability. Thus, even if VDDA is equal to VDDB, and the circuit 360 does not translate between voltage domains, it can act as an improved latch.

Returning to FIG. 6, the signal D represents an input data signal, CLK represents a clock signal, D_INT represents an intermediate data signal (e.g., D_INT illustrated in FIG. 4) and Q represents an output data signal. The x-axis represents time in nanoseconds, while the y axes represent voltage (e.g., in V for all three). At approximately time 0.68, the data signal D falls while the clock signal CLK is high. From time 0.68 to time 0.73 the value of D is neither low (e.g., 0V) nor high (e.g., 1.2V). It is in between.

In some latch designs (e.g., the latch 260 illustrated in FIG. 2B) the output data signal Q could become distorted during this interval, resulting in meta-stability and an output signal that is neither low nor high. But in the circuit 360, the output data signal Q remains high. In an embodiment, the regenerative feedback loop (e.g., between D_INT and QB in FIG. 4, as discussed above) pulls Q high while D transitions from high to low. As illustrated in FIG. 6, the output signal Q remains high through the clock interval from 0.6 to 0.8. The output signal Q then follows the input signal D and transitions to low at the next clock rise (e.g., at time 0.92).

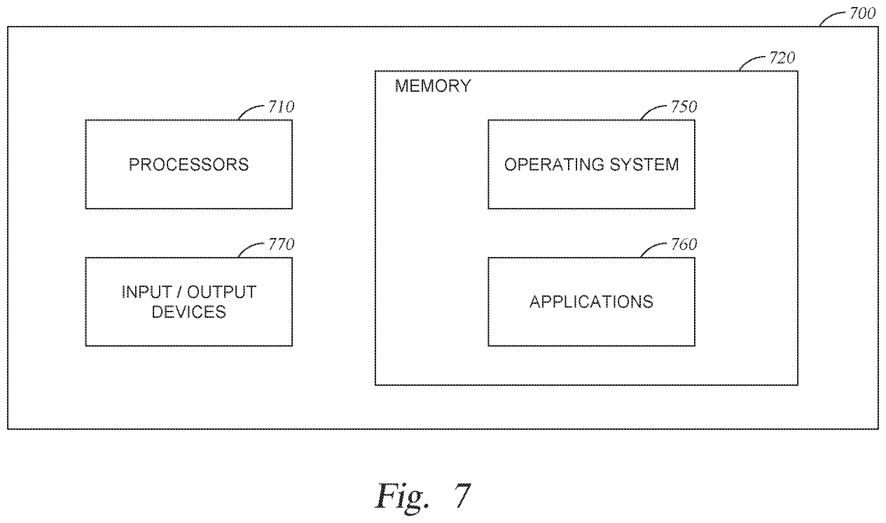

FIG. 7 illustrates an example computer 700, according to one embodiment described herein. Various methods, procedures, modules, flow diagrams, tools, applications, circuits, elements, and techniques discussed herein may also incorporate and/or utilize the capabilities of the computer 700. Moreover, capabilities of the computer 700 may be utilized to implement features of exemplary embodiments discussed herein. One or more of the capabilities of the computer 700 may be utilized to implement, incorporate, to connect to, and/or to support any element discussed herein (as understood by one skilled in the art) in FIGS. 1-6.

Generally, in terms of hardware architecture, the computer 700 may include one or more processors 710, computer readable storage memory 720, and one or more input and/or output (I/O) devices 770 that are communicatively coupled via a local interface (not shown). The local interface can be, for example but not limited to, one or more buses or other wired or wireless connections, as is known in the art. The local interface may have additional elements, such as controllers, buffers (caches), drivers, repeaters, and receivers, to enable communications. Further, the local interface may include address, control, and/or data connections to enable appropriate communications among the aforementioned components.

The processor 710 is a hardware device for executing software that can be stored in the memory 720. The processor 710 can be virtually any custom made or commercially available processor, a central processing unit (CPU), a data signal processor (DSP), or an auxiliary processor among several processors associated with the computer 700, and the processor 710 may be a semiconductor based microprocessor (in the form of a microchip) or a microprocessor. In an embodiment, the processor 710 can include one or more voltage level translator and latch circuits, as described above with regard to FIGS. 1-6. Note that the memory 720 can have a distributed architecture, where various components are situated remote from one another, but can be accessed by the processor 710.

The software in the computer readable memory 720 may include one or more separate programs, each of which comprises an ordered listing of executable instructions for implementing logical functions. The software in the memory 720 includes a suitable operating system (O/S) 750 and one or more applications 760 of the exemplary embodiments. As illustrated, the application 760 comprises numerous functional components for implementing the features, processes, methods, functions, and operations of the exemplary embodiments. The application 760 of the computer 700 may represent numerous applications, agents, software components, modules, interfaces, controllers, etc., as discussed herein but the application 760 is not meant to be a limitation.

The operating system 750 may control the execution of other computer programs, and provides scheduling, input-output control, file and data management, memory management, and communication control and related services.

The I/O devices 770 may include input devices (or peripherals) such as, for example but not limited to, a mouse, keyboard, scanner, microphone, camera, etc. Furthermore, the I/O devices 770 may also include output devices (or peripherals), for example but not limited to, a printer, display, etc. Finally, the I/O devices 770 may further include devices that communicate both inputs and outputs, for instance but not limited to, a NIC or modulator/demodulator (for accessing remote devices, other files, devices, systems, or a network), a radio frequency (RF) or other transceiver, a telephonic interface, a bridge, a router, etc. The I/O devices 770 also include components for communicating over various networks, such as the Internet or an intranet. The I/O devices 770 may be connected to and/or communicate with the processor 710 utilizing Bluetooth connections and cables (via, e.g., Universal Serial Bus (USB) ports, serial ports, parallel ports, FireWire, HDMI (High-Definition Multimedia Interface), PCIe, InfiniBand®, or proprietary interfaces, etc.).

When the computer 700 is in operation, the processor 710 is configured to execute software stored within the memory 720, to communicate data to and from the memory 720, and to generally control operations of the computer 700 pursuant to the software. The application 760 and the O/S 750 are read, in whole or in part, by the processor 710, perhaps buffered within the processor 710, and then executed.

It is understood that the computer 700 includes non-limiting examples of software and hardware components that may be included in various devices, servers, and systems discussed herein, and it is understood that additional software and hardware components may be included in the various devices and systems discussed in exemplary embodiments.

In some embodiments, various functions or acts may take place at a given location and/or in connection with the operation of one or more apparatuses or systems. In some embodiments, a portion of a given function or act may be performed at a first device or location, and the remainder of the function or act may be performed at one or more additional devices or locations.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the preceding features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present invention, other and further embodiments of the invention may be devised without departing from the basic scope thereof, and the scope thereof is determined by the claims that follow.

1. A microprocessor, comprising:
a first portion operating in a first voltage domain;
a second portion operating in a second voltage domain;
a circuit configured to translate a signal from the first voltage domain to the second voltage domain and to act as a latch for the signal both when the signal is in a logic high state and when the signal is in a logic low state, the circuit comprising:
a regenerative feedback loop, comprising:
an input node;
an output node;
a first inverter; and
a first transistor, wherein the input node is coupled to the first transistor and an input of the first inverter, and wherein the output node is coupled to an output of the first inverter and a gate of the first transistor.

2. The microprocessor of claim 1, wherein the circuit is driven by one or more voltage sources operating at a first rail voltage.

3. The microprocessor of claim 2, wherein the circuit is configured to translate the signal from the first voltage domain to the second voltage domain using only the one or more voltage sources operating at the first rail voltage.

4. The microprocessor of claim 3, wherein the first rail voltage is a rail voltage for the second voltage domain.

5. The microprocessor of claim 1, the circuit further comprising a switch coupled to the input node and a clock signal.

6. The microprocessor claim 5, wherein the circuit is configured to latch the signal using the clock signal.

7. The microprocessor of claim 1, the circuit further comprising a second inverter coupled to the output of the first inverter.

8. The microprocessor of claim 1, wherein the first transistor comprises a p-channel transistor and wherein the first transistor is coupled to the input node.

9. A combined voltage translator and latch circuit, comprising:
a circuit configured to translate a signal from a first voltage domain in an integrated circuit to a second voltage domain in the integrated circuit and to act as a latch for the signal both when the signal is in a logic high state and when the signal is in a logic low state, the circuit comprising:
a regenerative feedback loop, comprising:
an input node;
an output node;
a first inverter; and
a first transistor, wherein the input node is coupled to the first transistor and an input of the first inverter, and wherein the output node is coupled to an output of the first inverter and a gate of the first transistor.

10. The combined voltage translator and latch circuit of claim 9, wherein the circuit is driven by one or more voltage sources operating at a first rail voltage.

11. The combined voltage translator and latch circuit of claim 10, wherein the circuit is configured to translate the signal from the first voltage domain to the second voltage domain using only the one or more voltage sources operating at the first rail voltage.

12. The combined voltage translator and latch circuit of claim 11, wherein the first rail voltage is a rail voltage for the second voltage domain.

13. The combined voltage translator and latch circuit of claim 9, the circuit further comprising a switch coupled to the input node and a clock signal.

14. The combined voltage translator and latch circuit of claim 13, wherein the circuit is configured to latch the signal using the clock signal.

15. The combined voltage translator and latch circuit of claim 9, the circuit further comprising a second inverter coupled to the output of the first inverter.

16. A method for translating between voltage domains in a microprocessor, comprising:
translating a signal from a first voltage domain in a first portion of the microprocessor to a second voltage domain in a second portion of the microprocessor, using a circuit; and
latching the signal at the second voltage domain, using the circuit,
wherein the circuit is configured to latch the signal both when the signal is in a logic high state and when the signal is in a logic low state, and wherein the circuit comprises a regenerative feedback loop, comprising:
an input node;
an output node;
a first inverter; and
a first transistor, wherein the input node is coupled to the first transistor and an input of the first inverter, and wherein the output node is coupled to an output of the first inverter and a gate of the first transistor.

17. The method of claim 16, wherein the circuit is driven by one or more voltage sources operating at a first rail voltage.

18. The method of claim 17, wherein the circuit is configured to translate the signal from the first voltage domain to the second voltage domain using only the one or more voltage sources operating at the first rail voltage, and wherein the first rail voltage is a rail voltage for the second voltage domain.

19. The method of claim 16, the circuit further comprising a switch coupled to the input node and a clock signal.

20. The method of claim 19, wherein the circuit is configured to latch the signal using the clock signal.
